(19) United States
(12) Patent Application Publication
(10) Pub. No.: US 2026/0349028 A1
(43) Pub. Date: Nov. 5, 2026

(54) ALIGNMENT MARK DESIGN FOR WAFER-LEVEL TESTING AND METHOD FORMING THE SAME

(71) Applicant: Taiwan Semiconductor Manufacturing Co., Ltd., Hsinchu (TW)

(72) Inventors: Cheng-Chieh Wu, Taoyuan City (TW); Kuo-Lung Pan, Hsinchu (TW); Shu-Rong Chun, Zhubei City (TW); Hao-Yi Tsai, Hsinchu (TW); Po-Yuan Teng, Hsinchu (TW); Mao-Yen Chang, Kaohsiung City (TW); Cheng Yu Liu, Hsinchu (TW); Chia-Wen Lin, Hsinchu (TW)

(21) Appl. No.: 19/734,324

(22) Filed: Jul. 8, 2026

Related U.S. Application Data
(63) Continuation of application No. 18/151,621, filed on Jan. 9, 2023.
(60) Provisional application No. 63/368,371, filed on Jul. 14, 2022.
(60) Provisional application No. 63/376,355, filed on Sep. 20, 2022.

(51) Int. Cl. G01R 31/28; H10P 74/20; H10W 46/00

(52) U.S. Cl. CPC G01R 31/2891; H10P 74/207; H10W 46/00; H10W 46/301

(57) ABSTRACT

A method includes forming a reconstructed wafer, which includes placing a plurality of package components over a carrier, forming an interconnect structure over and electrically interconnecting the plurality of package components, forming top electrical connectors over and electrically connecting to the interconnect structure, and forming alignment marks at a same level as the top electrical connectors. Probe pads in the top electrical connectors are probed, and the probing is performed using the alignment marks for aligning to the probe pads. An additional package component is bonded to the reconstructed wafer through solder regions. The solder regions are physically joined to the top electrical connectors.

### PRIORITY CLAIM AND CROSS-REFERENCE

This application is a continuation of U.S. Patent Application No. 18/151,621, entitled “Alignment Mark Design for Wafer-Level Testing and Method Forming the Same,” filed on Jan. 9, 2023, which claims the benefit of the U.S. Provisional Application No. 63/376,355, filed Sep. 20, 2022, and entitled “Alignment Mark Design for Wafer-Level Testing and Method Forming the Same,” and U.S. Provisional Application No. 63/368,371, filed on Jul. 14, 2022, and entitled “UBM Design for Wafer Level Array Test Application,” which applications are hereby incorporated herein by reference.

### BACKGROUND

Packages of integrated circuits are becoming increasing complex, with more device dies being packaged in the same package to achieve more functions. For example, a package structure has been developed to include a plurality of device dies that have different functions. The package structure are electrically interconnected to form a system.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-10 illustrate the cross-sectional views of intermediate stages in a packaging process for forming a reconstructed wafer in accordance with some embodiments.

FIGS. 11A, 11B, 11C, and 11D illustrate a probing process of a reconstructed wafer in accordance with some embodiments.

FIG. 12 illustrates a reconstructed wafer after edge trimming processes in accordance with some embodiments.

FIG. 13 illustrates a magnified view of a part of a reconstructed wafer including alignment marks therein in accordance with some embodiments.

FIGS. 14A, 14B, 14C, 14D, 14E, 14F, and 14G illustrate some example alignment marks in accordance with some embodiments.

FIG. 15 illustrates a process flow for forming a reconstructed wafer in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A package, which may be a system-on-wafer package, and the method of forming the same are provided in accordance with some embodiments. The package includes a reconstructed wafer, which is formed by encapsulating a plurality of device dies. The plurality of device dies may include logic dies, Input-Output (IO) dies, and the like. A redistribution structure is formed to electrically and signally interconnect the plurality of device dies and to form a system. Top electrical connectors are formed at the top of the reconstructed wafer. The top electrical connectors include probe pads for probing and bond pads. Alignment marks are formed in the same formation process for forming the top electrical connectors, and are used for aligning probe pins to the probe pads. By forming the alignment marks in the same process as forming bond pads and probe pads, better alignment may be achieved. Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

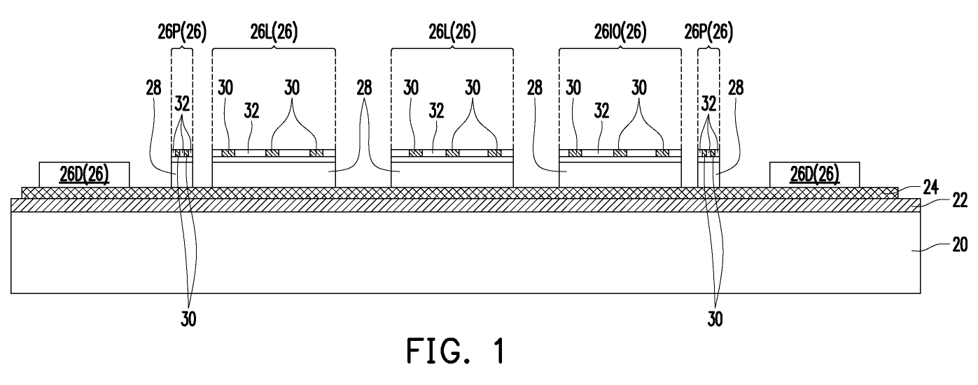

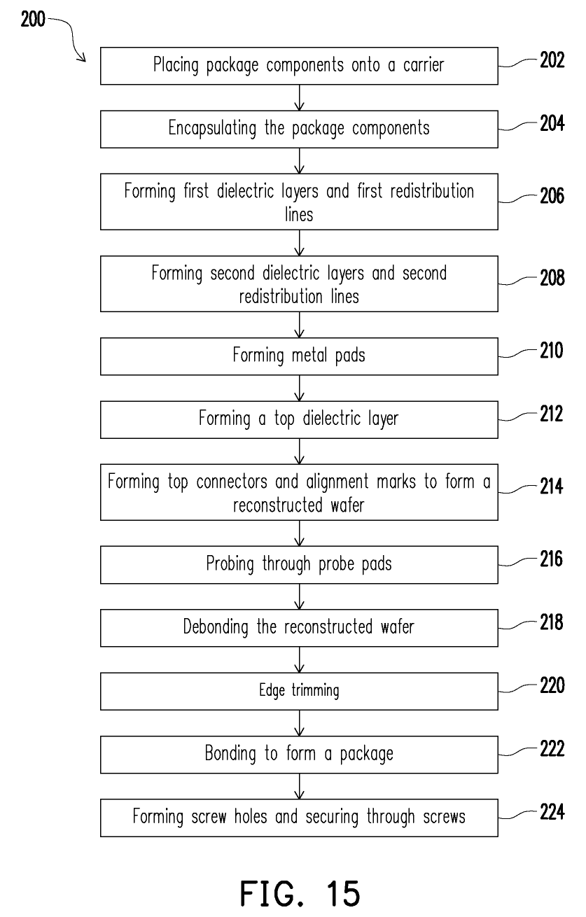

FIGS. 1-10, 11A, 11B, 11C, 11D, and 12 illustrate the cross-sectional views of intermediate stages in the formation of package in accordance with some embodiments of the present disclosure. The corresponding processes are also reflected schematically in the process flow 200 as shown in FIG. 15.

Referring to FIG. 1, carrier 20 is provided, and release film 22 is coated on carrier 20. Carrier 20 is formed of a transparent material, and may be a glass carrier, a ceramic carrier, an organic carrier, or the like. Release film 22 is in physical contact with the top surface of carrier 20. Release film 22 may be formed of a Light-To-Heat-Conversion (LTHC) coating material. Release film 22 may be applied onto carrier 20 through coating. In accordance with some embodiments of the present disclosure, the LTHC coating material is capable of being decomposed under the heat of light/radiation (such as a laser beam), and can release carrier 20 from the structure placed and formed thereon.

Die-Attach Film (DAF) 24, which is an adhesive film, is disposed on carrier 20. In accordance with some embodiments, as shown in FIG. 1, a single large die-attach film 24 is adopted, and all package components placed thereon are attached to the single large die-attach film 24. In accordance with alternative embodiments, each of the subsequently placed package components has an individual die-attach film attached underneath, wherein the individual die-attach films have edges flush with the edges of the respective overlying package components.

FIG. 1 further illustrates the placement of package components 26, which are placed on, and are attached to, die-attach film 24. The respective process is illustrated as process 202 in the process flow 200 as shown in FIG. 15. In accordance with some embodiments of the present disclosure, package components 26 include logic dies (such as computing dies), memory dies (such as Dynamic Random-Access Memory (DRAM) dies or Static Random-Access Memory (SRAM) dies), photonic dies, packages (including device dies that have already been packaged in), Input-output (IO) dies, digital dies, analog dies, die stacks such as High-Bandwidth Memory (HBM) blocks, or the like. Package components 26 may all be of the same type having an identical structure, or may include a plurality of different types of package components as aforementioned. In accordance with some embodiments, package components 26 include logic dies (also referred to as core device dies) 26L, IO dies 26IO, and dummy dies 26D. Package components 26 may also include some passive device dies 26P.

In accordance with some embodiments, dummy dies 26D are free from active integrated circuits and passive integrated circuits therein. Dummy dies 26D may be homogeneous dies formed of a homogeneous material such as silicon, and may be free from other features such as metal lines, dielectric layers, and the like formed thereon.

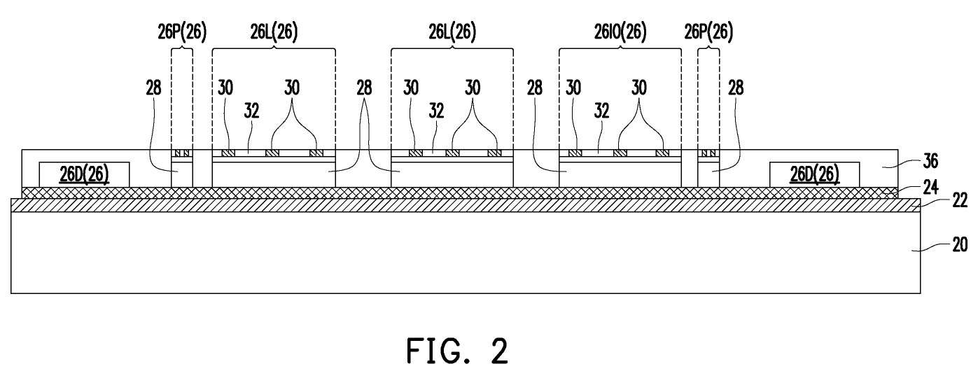

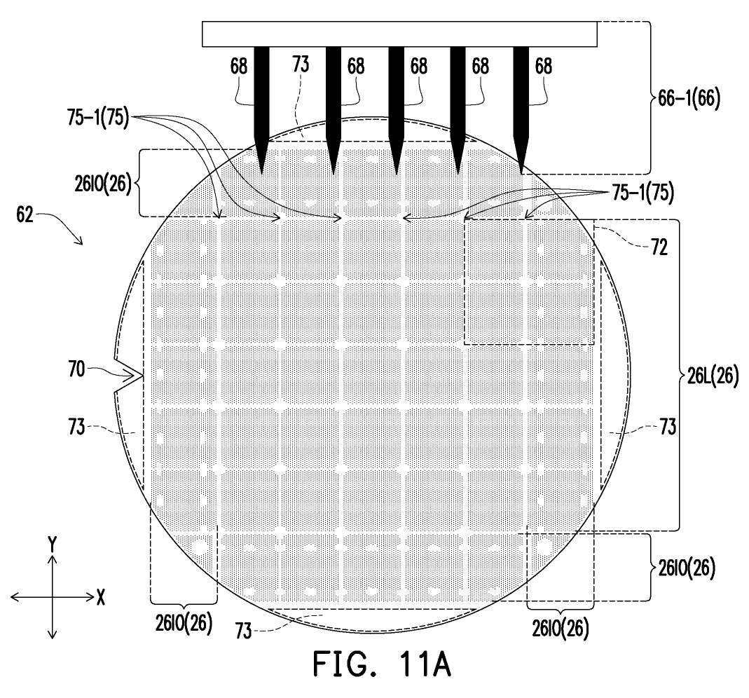

FIG. 11A illustrates a top view of the placed package components 26. In accordance with some embodiments, the logic dies 26L are placed as an array, and IO dies 26IO are placed surrounding logic dies 26L. Dummy dies 26D are not shown separately, and may be placed where the placed package components 26L and 26IO are sparse. For example, dummy dies 26D may be placed into the irregular-shaped regions on the outer sides of IO dies 26IO. Dummy dies 26D may also be placed between package components 26L and 26IO. Dummy dies 26D have the function of occupying the spaces that are otherwise occupied by the subsequently formed encapsulant 36 (FIG. 2), so that there will not be large areas of encapsulant 36. Otherwise, since the Coefficient of Thermal Expansion (CTE) of encapsulant 36 is significantly greater than the CTE of package components 26, the warpage cause by the CTE mismatch is high.

In accordance with some embodiments, package components 26 include semiconductor substrates 28, which may be silicon substrates, germanium substrates, or III-V compound semiconductor substrates formed of, for example, GaAs, InP, GaN, InGaAs, InAlAs, etc. Integrated circuit devices (not shown) such as transistors, diodes, resistors, capacitors, inductors, or the like, may be formed at the surfaces of, or over, substrates 28. Interconnect structures such as metal lines and vias, which are formed in dielectric layers, are formed over and electrically coupling to the integrated circuit devices. Conductive pillars 30 are formed at the surfaces of the corresponding package components 26, and are electrically coupled to the integrated circuit devices in package components 26 through the interconnect structures. Protection layers 32 are formed to cover conductive pillars 30 (also sometimes referred to as metal pillars 30). Protection layers 32 may be formed of a polymer such as polyimide, polybenzoxazole (PBO), or the like.

Referring to FIG. 2, encapsulant 36 is dispensed to encapsulate package components 26 and fills the gaps between package components 26. The respective process is illustrated as process 204 in the process flow 200 as shown in FIG. 15. The dispensed encapsulant 36 is then cured. Encapsulant 36 may include a molding compound, a molding underfill, an epoxy, and/or a resin. In accordance with some embodiments, encapsulant 36 includes a base material and filler particles in the base material. The base material may include a polymer, a resin, an epoxy, and/or the like. The filler particles may be formed of silicon oxide, aluminum oxide, or the like. which may have spherical shapes. Also, the spherical filler particles may have the same or different diameters.

Subsequent to the dispensing of encapsulant 36, a planarization process such as a Chemical Mechanical Polish (CMP) process or a mechanical grinding process is performed to planarize encapsulant 36, protection layers 32, and conductive pillars 30. As a result, conductive pillars 30 are exposed. In accordance with some embodiments, after the planarization process, dummy dies 26D are embedded in encapsulant 36, and are still covered by a layer of encapsulant 36. In accordance with alternative embodiments, after the planarization process, dummy dies 26D are revealed.

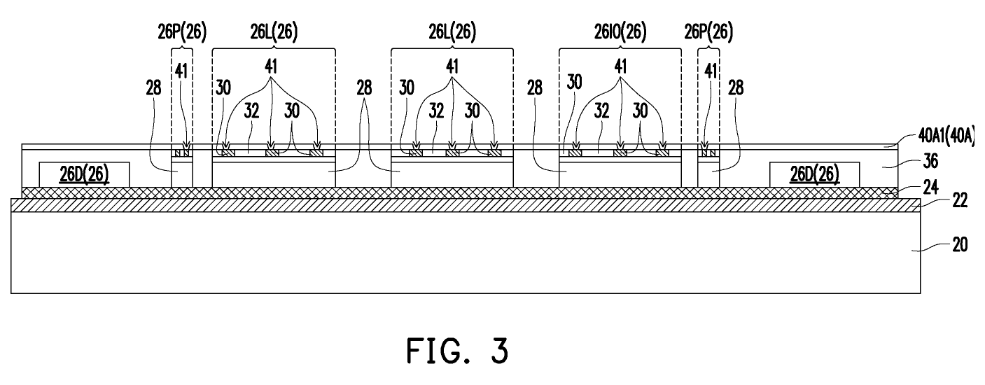

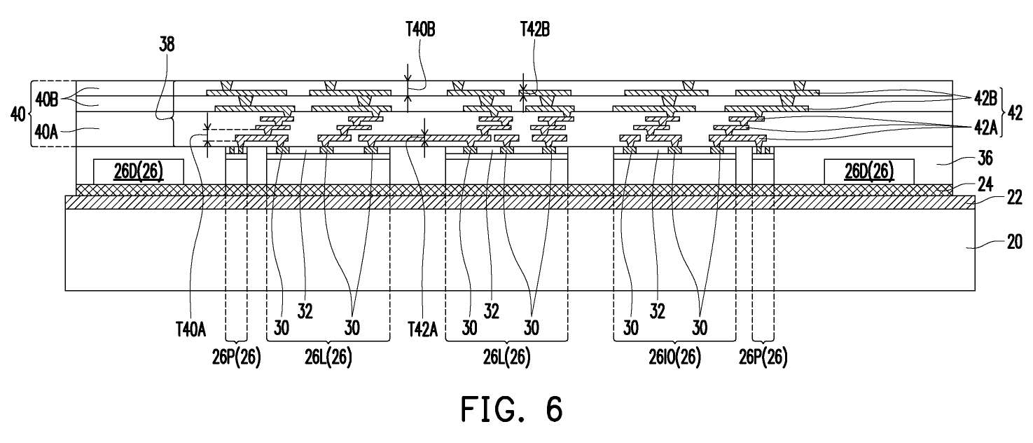

In subsequent processes, interconnect structure 38 (FIG. 6) is formed over encapsulant 36, as shown in FIGS. 3-6, which illustrate the formation of a lower portion and an upper portion, respectively, of interconnect structure 38. In accordance with some embodiments of the present disclosure, as shown in FIG. 6, interconnect structure 38 includes dielectric layers 40A and dielectric layers 40B over dielectric layers 40A, which are collectively referred to as dielectric layers 40. The boundaries between neighboring dielectric layers 40A are not shown, while the boundaries may be (or may not be), distinguishable. In accordance with some embodiments, dielectric layers 40B are thicker than dielectric layers 40A.

In accordance with some embodiments of the present disclosure, dielectric layers 40A are formed of a photo-sensitive polymer(s) such as PBO, polyimide, BCB, or the like, and dielectric layers 40B are formed of a non-photo-sensitive material(s) such as a molding compound(s), a molding underfill(s), silicon oxide, silicon nitride, or the like. In accordance with alternative embodiments, both of dielectric layers 40A and 40B are formed of photo-sensitive material(s). For example, all of dielectric layers 40 may be formed of photo-sensitive material(s) such as PBO, polyimide, BCB, or the like. The formation of each of dielectric layers 40A and 40B may include dispensing dielectric layer 40 in a flowable form, and then curing the dielectric layer 40.

RDLs 42A are formed in dielectric layers 40A, and RDLs 42B are formed in dielectric layers 40B. RDLs 42A and 42B are collectively referred to as RDLs 42. RDLs 42 electrically and signally interconnect package components 26 as a system. In accordance with some embodiments, RDLs 42B are thicker and/or wider (when viewed from top) than RDLs 42A, and may be used for long-range electrical routing, while RDLs 42A may be used for short-range electrical routing.

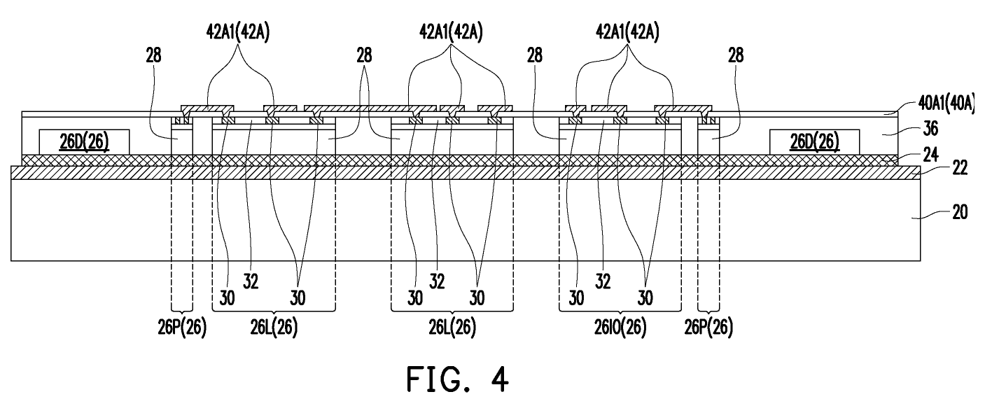

An example formation process of dielectric layers 40A and RDLs 42A are discussed as follows referring to FIGS. 3 and 4. The respective process is illustrated as process 206 in the process flow 200 as shown in FIG. 15. First, as shown in FIG. 3, a first dielectric layer (denoted as 40A1) in the dielectric layers 40A is deposited on the polished encapsulant 36 and package components 26. Dielectric layer 40A1 is then patterned to form openings 41, through which the metal pillars 30 of package components 26 are exposed. The patterning process may be performed through a photo lithography process including light-exposing the dielectric layer 40A1, and developing the dielectric layer 40A1.

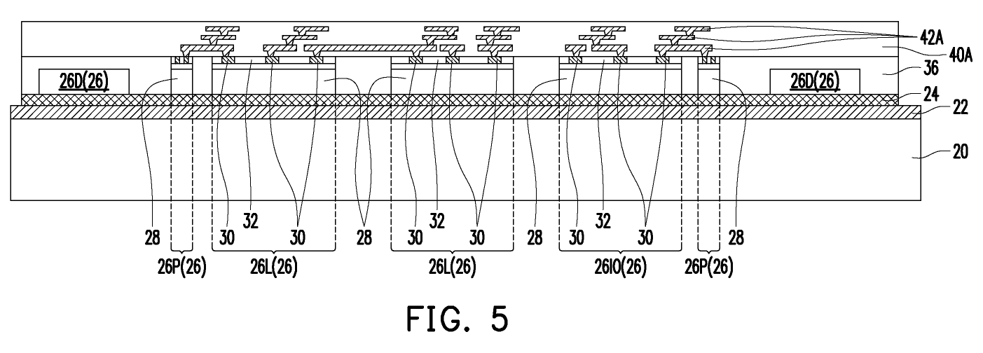

Next, a metal seed layer (not shown) is deposited, for example, through a Physical Vapor Deposition (PVD) process. The metal seed layer may include a titanium layer and a copper layer over the titanium layer. Alternatively, the metal seed layer may be a copper layer. A plating mask (not shown), which may be a photoresist, is then formed on the patterned dielectric layer 40A1, and is also patterned. A plating process is then performed to deposit a metallic material (such as copper, aluminum, aluminum copper, or the like) in the openings in the plating mask. The plating mask is then removed, followed by the etching of the underlying metal seed layer. As shown in FIG. 4, an RDL layer 42A1 is thus formed, and includes line portions overlying dielectric layer 40A1 and via portions extending into dielectric layer 40A1. This process may be repeated to form a plurality of dielectric layers 40A and the corresponding RDLs 42A, which is shown in FIG. 5. Accordingly, distinguishable interfaces may be formed between neighboring dielectric layers 40A, wherein the distinguishable interfaces may be at the same levels wherein metal lines are joined to the respective underlying vias.

Referring to FIG. 6, dielectric layers 40B and RDLs 42B are formed. The respective process is illustrated as process 208 in the process flow 200 as shown in FIG. 15. An example formation process of dielectric layers 40B and RDLs 42B are discussed as follows as an example. First, a metal seed layer is deposited, followed by the formation and the patterning of a first plating mask (not shown), which may be a photoresist. A first plating process is then performed to plate line portions of RDLs 42B. The first plating mask is then removed. Next, without etching the metal seed layer, a second plating mask (not shown) is formed, which may also be a photoresist. A second plating process is then performed to plate the via portions of the RDLs 42B. The second plating mask is then removed, followed by the etching of the underlying metal seed layer not covered by the line portions of RDLs 42A. A layer of RDLs and an overlying layer of vias are thus formed. Next, a dielectric layer 40B, for example, a molding compound, is disposed and cured. A planarization process is then performed, so that the top surfaces of the via portions of RDLs 42B are level with the top surface of the dielectric layer 40B. This process may be repeated to form a plurality of dielectric layers 40B and the corresponding RDLs 42B. Accordingly, distinguishable interfaces may be formed between neighboring dielectric layers 40B. The distinguishable interfaces may be at the same levels wherein the line portions contact the respective underlying vias, and may be distinguishable due to the planarization processes. Interconnect structure 38 is thus formed. Interconnect structure 38 electrically and signally interconnect package components 26 with each other to form a system.

In accordance with some embodiments, dielectric layers 40A are thinner than dielectric layers 40B. For example, the thickness T40A (FIG. 6) of each of dielectric layers 40A may be in the range between about 1 μm and about 10 μm, while the thickness T40B of each of dielectric layers 40B may be in the range between about 10 μm and about 40 μm. The thickness ratio T40B/T40A may be in the range between about 4 and about 10 in accordance with some embodiments. Also, the thickness T42B of RDLs 42B may be greater than the thickness T42A of RDLs 42A, so that that long-range electrical routing may have reduced resistance. The ratio T42B/T42A may also be in the same range as T40B/T40A, for example, in the range between about 4 and about 10.

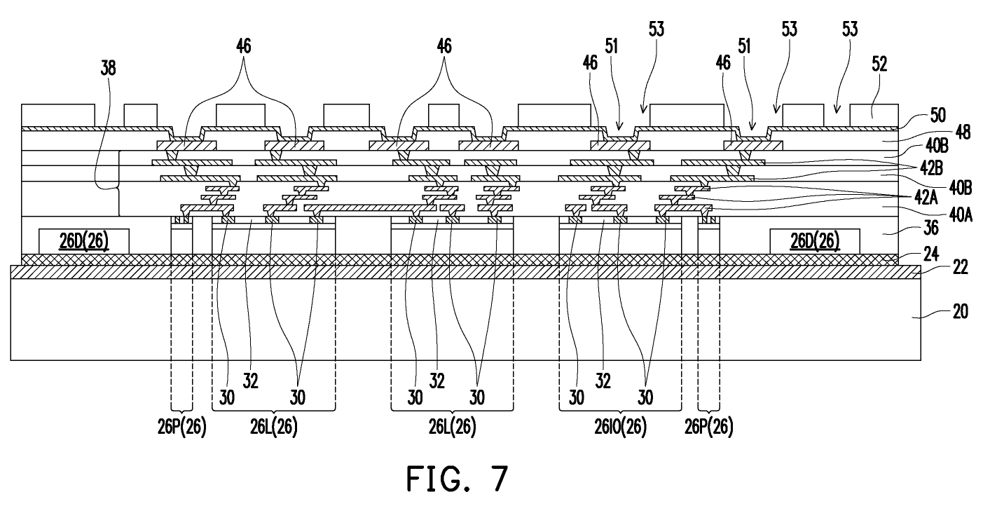

Referring to FIG. 7, metal lines (and pads) 46 are formed. The respective process is illustrated as process 210 in the process flow 200 as shown in FIG. 15. The formation process may also include forming a metal layer, forming a patterned plating mask, plating a metallic material, removing the patterned plating mask, and etching exposed portions of the metal seed layer.

Dielectric layer 48 is then formed. The respective process is illustrated as process 212 in the process flow 200 as shown in FIG. 15. In accordance with some embodiments, dielectric layer 48 is a polymer layer, and may be a photo-sensitive polymer layer. For example, dielectric layer 48 may be formed of or comprise a polymer such as polyimide, PBO, and the like. Openings 51 are formed in dielectric layer 48, for example, through a light-exposure process followed by a development process. The pad portions of metal lines 46 are thus exposed.

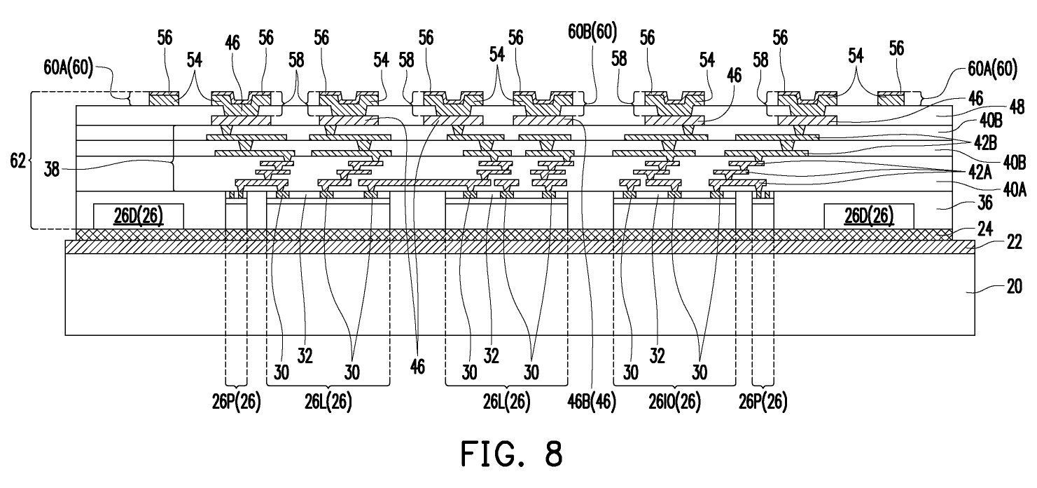

FIGS. 7 and 8 further illustrate the formation of top electrical connectors and alignment marks. The respective process is illustrated as process 214 in the process flow 200 as shown in FIG. 15. Referring to FIG. 7, metal seed layer 50 is deposited, for example, through PVD. Metal seed layer 50 may include a titanium layer and a copper layer over the titanium layer. Alternatively, the metal seed layer 50 may be a copper layer. Next plating mask 52 is formed. Plating mask 52 may be formed of a photo-sensitive material such as a photoresist. Plating mask 52 is patterned to form openings 53. In accordance with some embodiments in which plating mask 52 is formed of the photo-sensitive material, the patterning is performed by light-exposing plating mask 52, and then performing a development process. Openings 53 are thus formed, and some portions of metal seed layer 50 are revealed to openings 53.

In a subsequent process, a plating process(es) is performed to deposit one or a plurality of metallic materials in openings 53 and 51. In accordance with some embodiments, as shown in FIG. 8, solder layers are plated into openings 53 and 51. Before the formation of the solder layers 56, other non-solder metallic materials such as copper, aluminum, aluminum copper, or alloys thereof may be (or may not be) plated into openings 53 and 51. After the plating, plating mask 52 is removed, followed by the etching of the underlying metal seed layer 50. The resulting structure is also shown in FIG. 8. The remaining portions of the metal seed layer 50 and the plated non-solder metallic material (if any) are collectively referred to as electrical connectors 54. Electrical connectors 54 are alternatively referred to as Under-Bump Metallurgies (UBMs) or metal pillars in accordance with some embodiments.

Throughout the description, electrical connectors 54 and solder layers 56 are collectively referred to as top electrical connectors 58. Some of the top electrical connectors 58 are used for probing, and are also referred to as probe pads 58. Some other top electrical connectors 58 are used for bonding, and are alternatively referred to as bond pads 58 hereinafter. Probe pads 58 may be directly over or in the fanout region of IO dies 26IO.

In the same processes for forming top electrical connectors 58, alignment marks 60 are formed. Alignment marks 60 may have a plurality of different configurations. For example, alignment marks 60A may be formed over dielectric layer 48. An entirety of each of alignment marks 60A is over dielectric layer 48, and alignment marks 60A do not include vias extending into dielectric layer 48 to connect to the underlying metal pads 46. Accordingly, alignment marks 60A are electrically floating.

On the other hand, some of alignment marks 60, such as alignment mark 60B, may also include vias extending into dielectric layer 48 to contact the underlying metal pads 46 (marked as 46B). Accordingly, a metal pad 46B may act as anchor to secure the overlying alignment mark 60B, so that alignment mark 60B is less likely to peel off from dielectric layer 48. In accordance with some embodiments, metal pad 46B is not electrically connected to any other metallic feature (except alignment mark 60B) in dielectric layer 48 and underlying dielectric layers 40B. Accordingly, metal pad 46B and alignment mark 60B in combination is electrically floating. In accordance with some embodiments, metal pad 46B may be further connected to some underlying vias and metal pads for better anchoring, while metal pad 46B and alignment mark 60B in combination with the connected metal features are still electrically floating. Alignment mark 60B may also be electrically grounded in accordance with some embodiments.

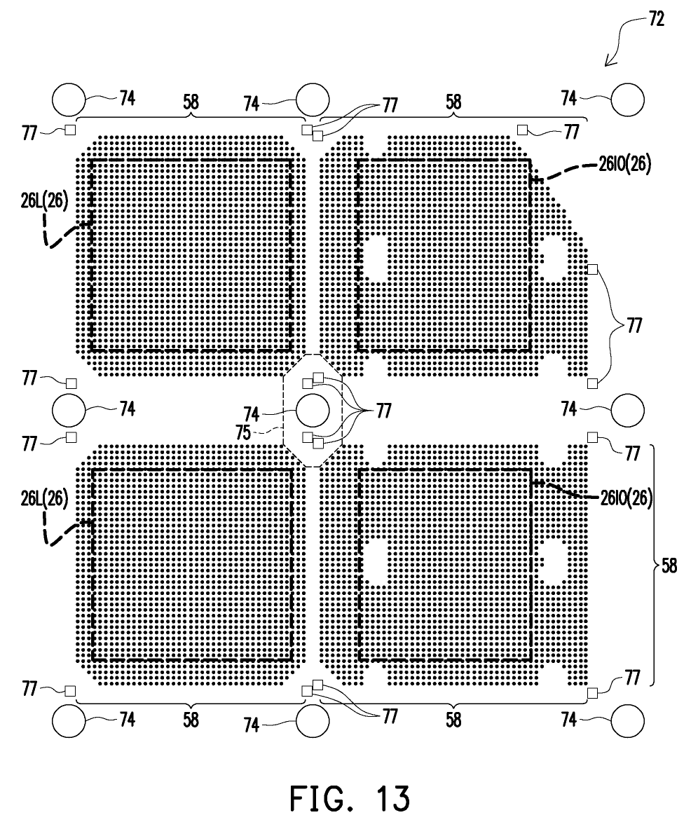

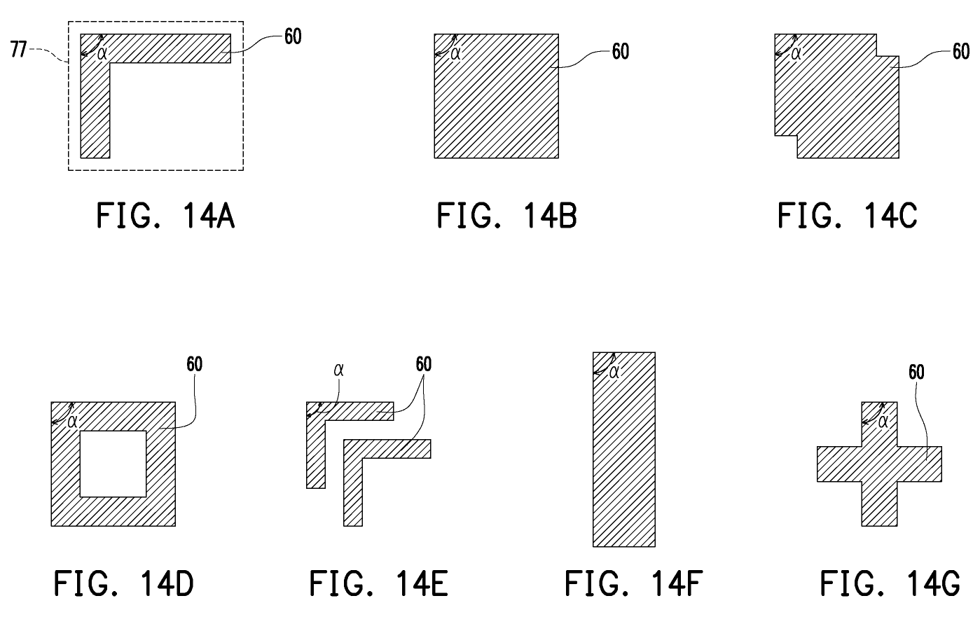

As will be discussed in subsequent paragraphs, some of top electrical connectors 58, which are electrically connected to package components, may also function as alignment marks. The top electrical connectors 58 used as alignment marks may be used for carrying power (such as carrying power voltage VDD or electrically grounded), or may be used for carrying electrical signals. For example, some of the top electrical connectors 58 may have the top-view shape as shown in FIGS. 14B, 14C, 14F, 14G, and the like. These top electrical connectors 58 may be designed to have certain shapes and sizes so that they can also be uniquely identified, and thus are also used as alignment marks. The top electrical connectors 58 used as alignment marks are placed in the same locations (such as corner regions 75) in which other alignment marks are located, as discussed referring to FIG. 13. The top electrical connectors 58 used as alignment marks may also be used in combination with alignment marks 60 for identifying the top electrical connectors 58 that will be used as probe pads.

Throughout the description, as shown in FIG. 8, the portions of the structure higher than die-attach film 24 are collectively referred to as reconstructed wafer 62, which includes package components 26, encapsulant 36, dielectric layers 40A, 40B and 48, RDLs 42A and 42B, metal pads 46, top electrical connectors 58, and alignment marks 60. Reconstructed wafer 62 may have a round top-view shape. FIG. 11A illustrates a top view of reconstructed wafer 62 in accordance with some embodiments. Logic dies 26L may be arranged in an inner region of reconstructed wafer 62, and may form an array. IO dies 26IO may be located in a peripheral region(s) of reconstructed wafer 62, and may be arranged, for example, as four rows, each aligned in a straight line in X direction or Y direction. Dummy dies 26D (not shown) may be arranged in regions 73, which are on the further outer side of IO dies 26IO. Also, some of dummy dies 26D may be arranged in the inner region of reconstructed wafer 62, and some of dummy dies 26D may be arranged between IO dies 26IO.

In accordance with some embodiments, as shown in FIG. 11A, reconstructed wafer 62 may have a round top-view shape, while other top-view shapes such as rectangular top-view shapes may be adopted. A notch 70 is formed on a side of reconstructed wafer 62, so that the direction of reconstructed wafer 62 can be determined. In accordance with some example embodiments, reconstructed wafer 62 has four rows of IO dies 26IO, with a first row (referred to as a top row hereinafter) close to the illustrated top edge of reconstructed wafer 62, with the row extending in the X direction. IO dies 26IO may also include a second row (referred to as a bottom row hereinafter) close to the illustrated bottom edge of reconstructed wafer 62, with the row also extending in the X direction. IO dies 26IO may also include a third row (referred to as a right row hereinafter) close to the illustrated right edge of reconstructed wafer 62, with the row extending in the Y direction. IO dies 26IO may also include a fourth row (referred to as a left row hereinafter) close to the illustrated left edge of reconstructed wafer 62, with the row extending in the Y direction. It is appreciated that the logic dies and IO dies may be arranged in any applicable arrangement other than illustrated.

FIG. 13 illustrates a magnified view of a portion 72 (FIG. 11A) of reconstructed wafer 62 in accordance with some embodiments. As shown in FIG. 13, the illustrated portion 72 includes four package components 26. When the portion 72 is at the position shown in FIG. 11A, the four package components may include two logic dies 26L and two IO dies 26IO. When portion 72 is at other positions other than the position shown in FIG. 11A, the four package components may include different combinations of logic dies 26L and IO dies 26IO. A plurality of electrical connectors 58 are over each of the logic dies 26L and IO dies 26IO, and may or may not fanout from the respective underlying logic dies 26L and IO dies 26IO. The plurality of electrical connectors 58 form a plurality of groups. Every four neighboring package components 26 (and neighboring top electrical connectors 58) may define a corner region 75, with one corner region 75 marked. In the top view of FIG. 13, the corner regions 75 may be free from both of package components 26 and electrical connectors 58. As will be discussed in subsequent paragraphs, screw holes 74 are formed in the corner regions 75.

Alignment marks 60 may be formed in the corner regions 75, and are formed out of the regions where screw holes 74 are to be formed. FIG. 13 illustrates regions 77, in each an alignment mark 60 is formed. An example region 77 and the corresponding alignment mark 60 therein are illustrated in FIG. 14A. By forming alignment marks 60 out of the regions in which screw holes 74 are formed, it is possible to probe reconstructed wafer 62 after the formation of screw holes 74. Otherwise, alignment marks will be removed due to the formation of reconstructed wafer 62. Furthermore, by forming alignment marks 60 out of the regions in which screw holes 74 are formed, during the formation of screw holes 74, no metal is drilled, and the possibility of damaging reconstructed wafer 62 due to the tearing of metal is avoided.

FIGS. 11A, 11B, 11C, and 11D illustrate some example probing processes. The respective process is illustrated as process 216 in the process flow 200 as shown in FIG. 15. Referring back to FIG. 11A, a plurality of corner regions 75-1 (which are also corner regions 75) have alignment marks formed therein, which alignment marks are a sub set of all alignment marks. The details of the alignment marks and corner regions 75 are shown in FIG. 13. The sub set of alignment marks in corner regions 75 are used for aligning to the probe pads over the top row of IO dies 26IO. A first probing process is then performed on these probe pads using a first probe card 66-1. Alignment marks 60 have unique shapes that are different from top electrical connectors 58, so they can be easily identified. Once alignment marks 60 are found, the positions of the probe pads 58, which are offset in certain directions for certain distance, may be found, and are probed using probe card 66-1.

Next, as shown in FIG. 11B, reconstructed wafer 62 may be rotated, for example, by 90 degrees, and the previous left row of IO dies 26IO shown in FIG. 11A now become the top row in FIG. 11B. The rotation may be recognized by referring to the position of notch 70. The sub set of alignment marks in corner regions 75-2 are used to identify the positions of the probe pads over the now-top-row of IO dies 26IO. The alignment marks in corner regions 75-2 may be different from the alignment marks in corner regions 75-1, and their difference may include the difference in numbers, patterns, positions, spacings, and/or the like. Accordingly, the alignment marks in corner regions 75-2 may be distinguished from the alignment marks in corner regions 75-1. Another probe card 66-2, which may be different from probe card 66-1 (FIG. 11A), may be selected and used for probing the corresponding probe pads.

FIG. 11C illustrates the further rotation of reconstructed wafer 62 by 90 degrees again (refer to the position of notch 70). The corresponding probe cards over IO dies 26IO in the now-top-row thus may be identified, and a third probing process is performed. Again, the sub set of alignment marks in corner regions 75-3 are different from, and may be distinguished from, the alignment marks in corner regions 75-1 and 75-2, so that a proper probe card 66-3, which may be different from probe cards 66-1 and 66-2, may be selected and used to perform the third probing process.

FIG. 11D illustrates the further rotation of reconstructed wafer 62 by 90 degrees again (refer to the position of notch 70). The corresponding probe cards over IO dies 26IO in the now-top-row thus may be identified, and a fourth probing process is performed. Again, the sub set of alignment marks in corner regions 75-4 are different from, and may be distinguished from, the alignment marks in corner regions 75-1, 75-2, and 75-3, so that a proper probe card 66-4, which may be different from probe cards 66-1, 66-2, and 66-3, may be selected and used to perform the fourth probing process.

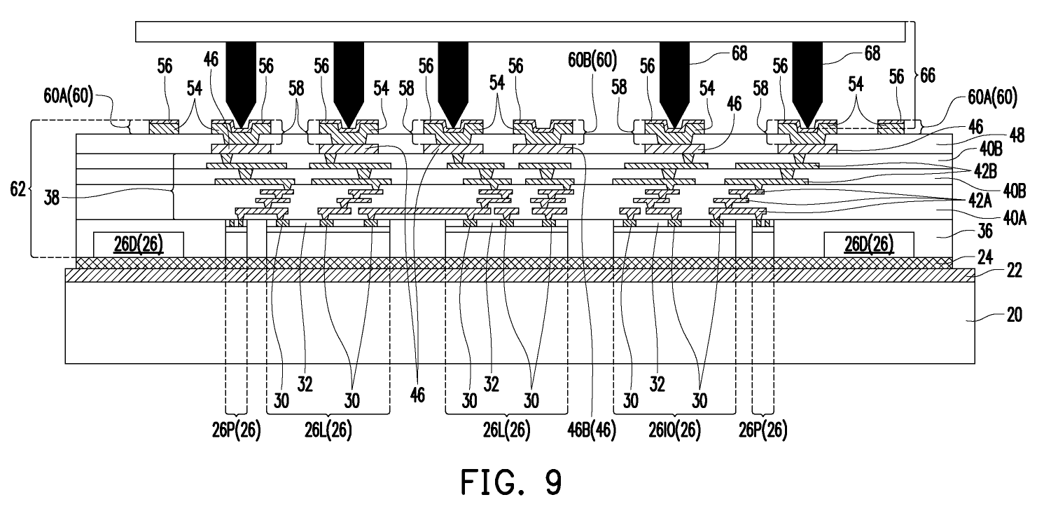

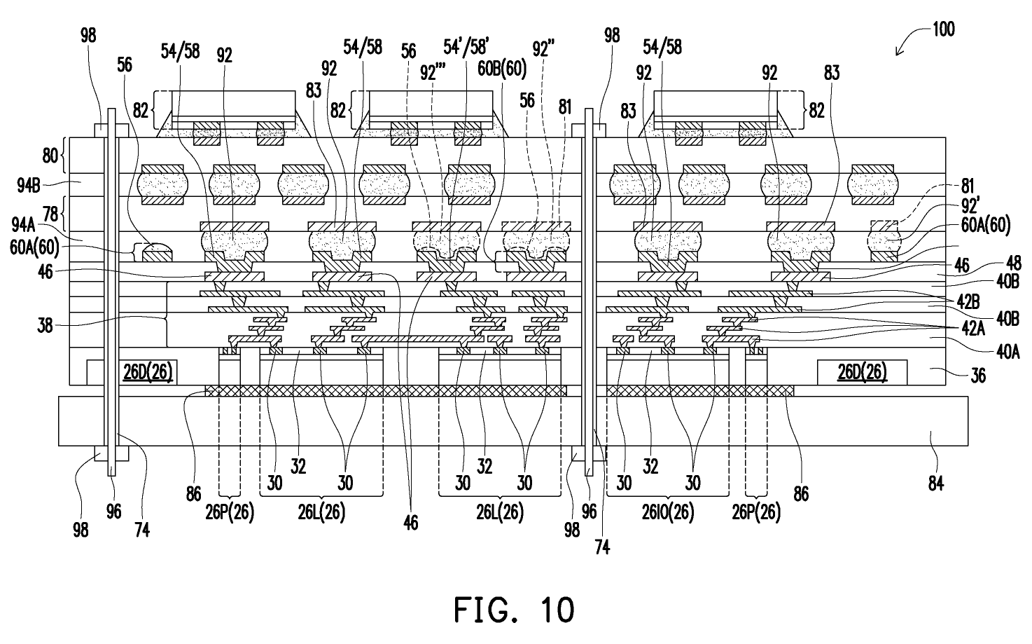

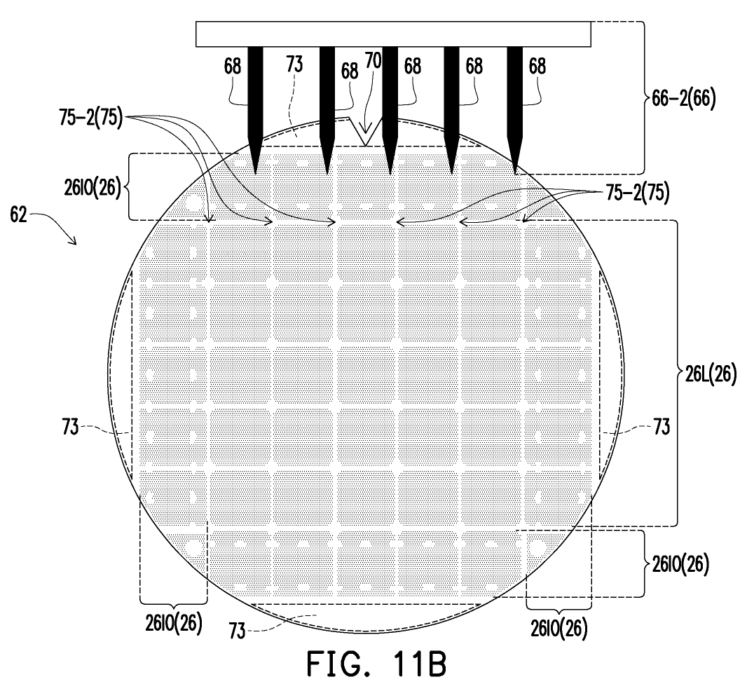

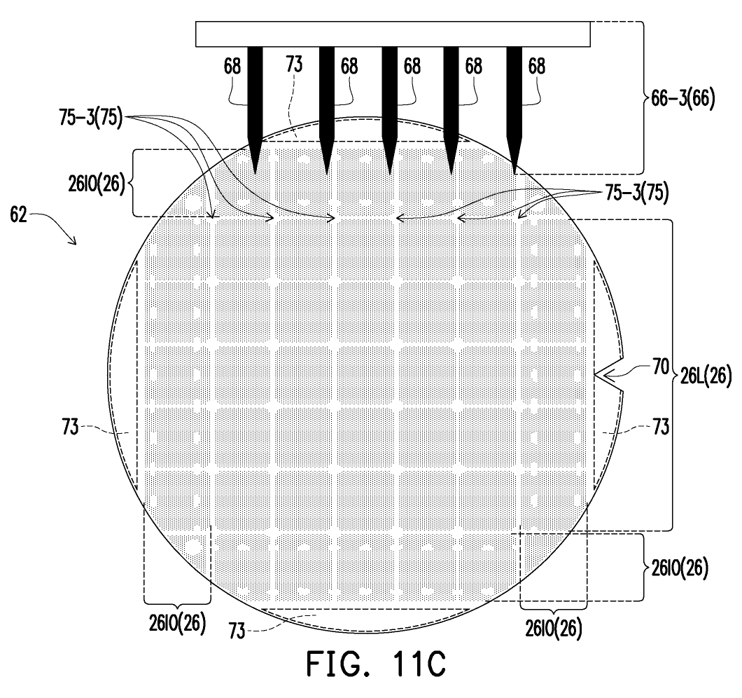

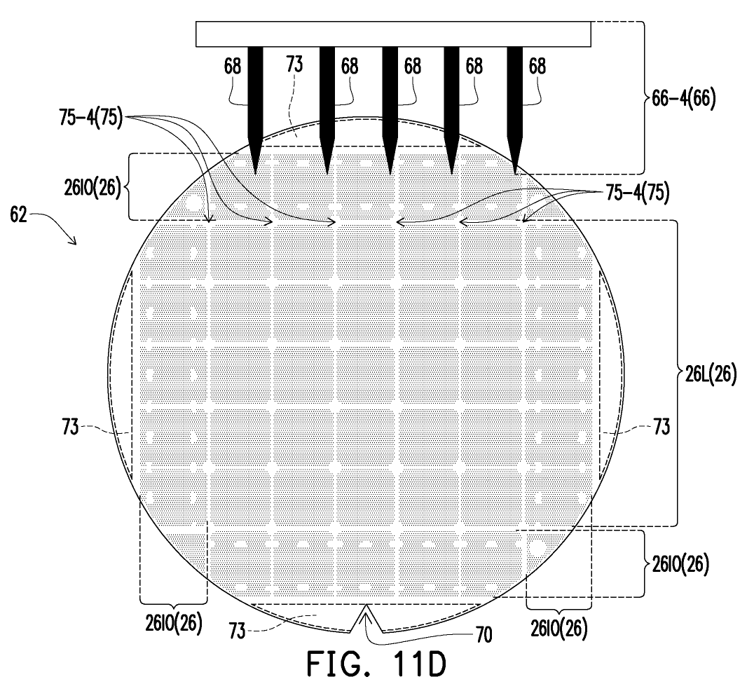

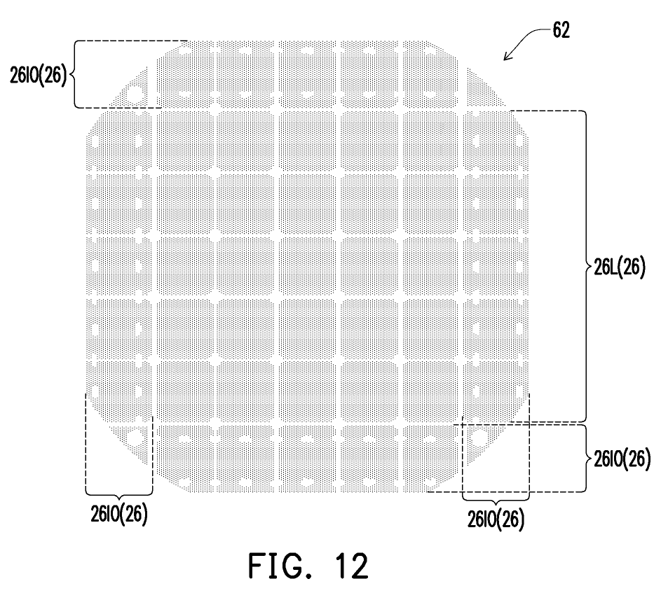

The probing processes are used to determine the defects (if any) in reconstructed wafer 62 and to determine the functionality of reconstructed wafer 62. The probing processes are also shown in FIG. 9. In accordance with some embodiments, the probing is performed by using a probe card 66, which includes probe pins 68. Probe pins 68 are put into contact with the top electrical connectors 58 that are designed for probing. The probe pads 58 that are designed for probing may be signally connected to IO dies 26IO. In accordance with some embodiments, as shown in FIG. 9, the probing is performed when reconstructed wafer 62 is located on carrier 20. In accordance with alternative embodiments, the probing is performed after reconstructed wafer 62 has been de-bonded from carrier 20, and may be performed before or after the subsequently discussed through-hole formation process as shown in FIG. 10, and/or the trimming process as shown in FIG. 12.

In a subsequent process, reconstructed wafer 62 is de-bonded from carrier 20. for example, by projecting a light beam (such as a laser beam) on release film 22, and the light penetrates through the transparent carrier 20. The respective process is illustrated as process 218 in the process flow 200 as shown in FIG. 15. The release film 22 is thus decomposed, and reconstructed wafer 62 is released from carrier 20. DAF 24 may be removed in a cleaning process or a grinding process.

FIG. 12 illustrates an edge trimming process to trim the edge portions of reconstructed wafer 62. The respective process is illustrated as process 220 in the process flow 200 as shown in FIG. 15. In accordance with some embodiments, the edge trimming process removes some edge portions of reconstructed wafer 62, while leaving some other portions un-removed. The removed edge portions are free from package components 26, redistribution structure, and top electrical connectors 58 and alignment marks 60 therein. The removed edge portions may or may not include dummy dies 26D. In accordance with some embodiments, as shown in FIG. 12, reconstructed wafer 62 include straight edges, which are formed by the edge trimming process, and curved edges, which are the remaining portions of the original circular edge. In accordance with alternative embodiments, no edge trimming process is performed, and the round reconstructed wafer 62 is used in the subsequent bonding process.

Referring to FIG. 10, reconstructed wafer 62, which may be edge-trimmed or not edge-trimmed, is bonded to other package components to form package 100. The respective process is illustrated as process 222 in the process flow 200 as shown in FIG. 15. For example, FIG. 10 illustrates an example embodiment in which reconstructed wafer 62 is bonded to package components 78 and 80. In accordance with some embodiments, package components 78 and 80 include reconstructed wafers, interposers, package substrates, and/or the like. The bonding may be performed through solder bonding, hybrid bonding, metal-to-metal direct bonding, and/or the like.

FIG. 10 further illustrates some example discrete package components 82 bonding to the underlying package components. Package components 82 may be or may include power modules, sockets, and or the like. In accordance with some embodiments, cold plate (heat sink) 84 is attached to reconstructed wafer 62, for example, through Thermal Interface material (TIM) 86. Underfill 94A may be applied between reconstructed wafer 62 and package component 78, and underfill 94B may be applied between package components 78 and 80. Package 100, which is a wafer-level package including a system therein, is thus formed.

In accordance with some embodiments, top electrical connectors 58 are bonded to electrical connectors 83 in package component 78 through solder regions 92. Some or all of alignment marks 60 (such as the alignment mark 60A on the right side of FIG. 10) may be bonded to the dummy metal pads 81 in package components 26 through solder regions 92’. Dummy metal pads 81, solder regions 92’, and the corresponding alignment marks 60A may be electrically floating after the bonding, and may have the function of reducing package warpage.

Some or all of alignment marks 60 (such as the alignment mark 60A on the left side of FIG. 10) may not be bonded to package component 78. In these alignment marks 60A, the corresponding solder layers 56 therein will also be reflowed, and have curved top surfaces. The top surface of solder layer 56 is in contact with underfill 94A. Some or all of alignment marks 60B may also be, or may not be, bonded to package component 78. Accordingly, the respective solder region 92’’ and the overlying dummy bond pad 81 are shown as being dashed to indicate the solder region 92’’ and the overlying dummy bond 81 may or may not exist. A dashed line is also drawn to show the shape of the corresponding solder layer 56 when solder region 92’’ is not formed.

The probe pads may or may not be bonded to package component 78 through solder regions. For example, the probe pads marked as 54’/58’ may have a solder region 92’’’ bonding it to package component 78. Alternatively, solder region 92’’’ may not be formed. As a result, the corresponding solder layer 56 (alternatively referred to as solder region 56) will be curved, as shown by a dashed line.

Further referring to FIG. 10, screw holes 74 are formed to penetrate through reconstructed wafer 62. The respective process is illustrated as process 224 in the process flow 200 as shown in FIG. 15. Screw holes 74 may be formed through laser drill, drilling using a drill bit, or the like. Furthermore, screw holes 74 may be formed in reconstructed wafer 62 before or after the bonding of reconstructed wafer 62 with other package components to form package 100. When formed after the bonding of reconstructed wafer 62 with other package components, screw holes 74 also extend into other packages components 78 and 80. As shown in FIG. 13, screw holes 74 are formed in the corner regions 75 of package components 26, and may be away from alignment marks 60. Next, as also shown in FIG. 10, package 100 is secured through screws 96 and bolts 98. The respective process is also illustrated as process 224 in the process flow 200 as shown in FIG. 15.

FIGS. 14A, 14B, 14C, 14D, 14E, 14F, and 14G illustrate the top views of some example alignment marks 60. The alignment marks 60 shown in these figures may be used collectively in the same reconstructed wafer 62 in any combination. For example, one combination of selected alignment marks in these figures may be used for the alignment in FIG. 11A, while another combination of the alignment marks in these figures may be used for the alignment in FIG. 11B. The angles α of alignment marks 60 may be right angles, acute angles, or obtuse angles, and may be in the range between about 75° and about 105°.

In above-illustrated embodiments, some processes and features are discussed in accordance with some embodiments of the present disclosure to form a three-dimensional (3D) package. Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The embodiments of the present disclosure have some advantageous features. By forming alignment marks as top surface features of a reconstructed wafer and in the same processes as forming top electrical connectors, the alignment marks will not be covered by any surface dielectric layer, and hence can be clearly identified for the alignment of probe pins. In addition, the alignment marks are formed outside of the regions in which screw holes are formed, and hence may be found in the final package.

In accordance with some embodiments of the present disclosure, a method comprises forming a reconstructed wafer comprising placing a plurality of package components over a carrier; forming an interconnect structure over and electrically interconnecting the plurality of package components; forming top electrical connectors over and electrically connecting to the interconnect structure; and forming alignment marks at a same level as the top electrical connectors; probing probe pads in the top electrical connectors, wherein the probing is performed using the alignment marks for aligning to the probe pads; and bonding an additional package component to the reconstructed wafer through solder regions, wherein the solder regions are physically joined to the top electrical connectors.

In an embodiment, the method further comprises dispensing an underfill between, and in contact with, the reconstructed wafer and the additional package component, wherein the underfill contacts the alignment marks. In an embodiment, after the bonding, an entire top surface of one of the alignment marks is covered by the underfill. In an embodiment, after the bonding, one of the solder regions bonds one of the alignment marks to the additional package component. In an embodiment, the top electrical connectors are arranged as a plurality of groups, with corner regions between the plurality of groups being free from the top electrical connectors, and wherein the alignment marks are formed in the corner regions.

In an embodiment, the method further comprises drilling a plurality of holes in the reconstructed wafer, each in one of the corner regions, wherein the plurality of holes are spaced apart from the alignment marks. In an embodiment, the probing is performed using a sub set of the alignment marks to align to the probe pads, and wherein the sub set of the alignment marks is distributed in a plurality of corner regions that are arranged as a row. In an embodiment, the forming the alignment marks and the forming the top electrical connectors share common formation processes.

In an embodiment, the method further comprises forming a top surface dielectric layer over the interconnect structure, wherein an entirety of one of the alignment marks is over the top surface dielectric layer. In an embodiment, the method further comprises forming a metal pad over, and electrically disconnected from, the interconnect structure; forming a top surface dielectric layer over the metal pad; and forming an opening in the top surface dielectric layer to reveal the metal pad, wherein one of the alignment marks comprises a via in the opening, and a line portion over the top surface dielectric layer.

In accordance with some embodiments of the present disclosure, a method comprises encapsulating a plurality of device dies in an encapsulant; forming an interconnect structure over and electrically connecting to the plurality of device dies; forming a plurality of metal pads over and electrically connecting to the interconnect structure; forming a surface dielectric layer over the plurality of metal pads; forming via openings in the surface dielectric layer; forming top electrical connectors, each comprising a via portion extending into the surface dielectric layer; a pad portion over and joined to the via portion; and a first solder layer over the pad portion; forming a first alignment mark over the surface dielectric layer; bonding bond pads in the top electrical connectors to an additional package component; and dispensing an underfill, wherein the underfill contacts both of the top electrical connectors and the first alignment mark.

In an embodiment, at a time after the bonding, the first alignment mark is electrically floating. In an embodiment, the method further comprises probing probe pads in the top electrical connectors, wherein the probing is performed using the first alignment mark for alignment. In an embodiment, the first alignment mark and the top electrical connectors are formed through common plating processes. In an embodiment, the first alignment mark comprises a non-solder portion, and a second solder layer over the non-solder portion. In an embodiment, the method further comprises forming a second alignment mark, wherein the second alignment mark extends into the surface dielectric layer to contact an underlying metal pad, and wherein the second alignment mark and the underlying metal pad are in combination electrically floating.

In accordance with some embodiments of the present disclosure, a method comprises encapsulating a plurality of device dies in an encapsulant; forming an interconnect structure over and electrically connecting to the plurality of device dies; forming a plurality of metal pads over and electrically connecting to the interconnect structure; forming a surface dielectric layer over the plurality of metal pads; forming top electrical connectors over and electrically connecting to the interconnect structure; forming a plurality of alignment marks, wherein the forming the top electrical connectors and the forming the plurality of alignment marks share common processes; probing probe pads in the top electrical connectors, wherein the probing is performed by using the plurality of alignment marks for aligning to the probe pads; and bonding the top electrical connectors to an additional package component.

In an embodiment, after the bonding, the plurality of alignment marks are electrically floating. In an embodiment, the method further comprises dispensing an underfill, wherein the underfill contacts sidewalls of both of the top electrical connectors and the plurality of alignment marks. In an embodiment, the plurality of alignment marks are bonded to the additional package component through additional solder layers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming an interconnect structure over and electrically interconnected to a plurality of package components;
forming a patterned top dielectric layer over the interconnect structure;
depositing a metal seed layer, wherein the metal seed layer comprises portions in the patterned top dielectric layer to connect to underlying features;
plating top electrical connectors and a first alignment mark, wherein the top electrical connectors are electrically connected to the interconnect structure; and
probing probe pads in the top electrical connectors, wherein the probing is performed using the first alignment mark for aligning to the probe pads.

2. The method of claim 1, wherein the top electrical connectors and the first alignment mark comprise parts of the metal seed layer.

3. The method of claim 1 further comprising bonding an additional package component to the top electrical connectors through solder regions, wherein the solder regions are physically joined to the top electrical connectors.

4. The method of claim 3, wherein after the bonding, one of the solder regions bonds the first alignment mark to the additional package component.

5. The method of claim 3 further comprising dispensing an underfill contacting the top electrical connectors, wherein the underfill contacts a top surface the first alignment mark.

6. The method of claim 1, wherein the forming the first alignment mark comprises plating a non-solder material and a solder layer over the non-solder material.

7. The method of claim 1, wherein the top electrical connectors are arranged as a plurality of groups, with corner regions between the plurality of groups being free from the top electrical connectors, and wherein alignment marks are formed in the corner regions.

8. The method of claim 7 further comprising drilling a plurality of holes in the reconstructed wafer, each in one of the corner regions, wherein the plurality of holes are spaced apart from all alignment marks that are over the patterned top dielectric layer.

9. The method of claim 1, wherein the patterned top dielectric layer is free from conductive features in the patterned top dielectric layer, with the conductive features being also electrically connected to the first alignment mark.

10. The method of claim 1, wherein the first alignment mark comprises a pad portion over the patterned top dielectric layer and a via in the patterned top dielectric layer, and wherein the pad portion and the via are both formed by the plating.

11. A method comprising:
encapsulating a plurality of device dies in an encapsulant;
forming an interconnect structure over and electrically connecting to the plurality of device dies;
forming a plurality of metal pads over and electrically connecting to the interconnect structure;
forming a top dielectric layer over the plurality of metal pads;
forming via openings in the top dielectric layer, with the plurality of metal pads being exposed to the via openings;
forming top electrical connectors comprising:
via portions in the top dielectric layer;
pad portions over and joined to the via portions; and
solder layers over the pad portions;
forming a plurality of alignment marks over the top dielectric layer, wherein the plurality of alignment marks comprise a first alignment mark;
bonding bond pads in the top electrical connectors to an additional package component, wherein after the bonding, the first alignment mark is electrically floating; and
dispensing an underfill, wherein the underfill contacts both of the top electrical connectors and the first alignment mark.

12. The method of claim 11, wherein the first alignment mark is electrically connected to the additional package component.

13. The method of claim 11, wherein the plurality of alignment marks further comprise a second alignment mark, and wherein after the underfill is dispensed, the second alignment mark has a top surface contacting the underfill to form an interface.

14. The method of claim 11 further comprising probing on probe pads that are comprised in the top electrical connectors, wherein the probing is performed using the plurality of alignment marks for alignment.

15. The method of claim 11, wherein one of the top electrical connectors comprises a straight edge, and wherein the straight edge forms a straight interface with the underfill.

16. The method of claim 15, wherein an entirety of the straight interface is in contact with the underfill.

17. The method of claim 11, wherein the plurality of alignment marks are formed by processes comprising:
plating a non-solder portion; and
plating solder over the non-solder portion.

18. A method comprising:
encapsulating a plurality of device dies in an encapsulant;
forming an interconnect structure over and electrically connecting to the plurality of device dies;
forming a top dielectric layer over the interconnect structure;
forming top electrical connectors over and electrically connecting to the interconnect structure;
forming a plurality of alignment marks;
probing probe pads in the top electrical connectors, wherein the probing is performed by using the plurality of alignment marks for aligning to the probe pads;
bonding the top electrical connectors to an additional package component; and
applying an underfill to physically contact both of the top electrical connectors and the plurality of alignment marks.

19. The method of claim 18, wherein a first alignment mark of the plurality of alignment marks is electrically floating.

20. The method of claim 19, wherein a second alignment mark is configured to carrier power or signal.
